(19) United States
(12) Patent Application Publication
(10) Pub. No.: US 2025/0275377 A1
(43) Pub. Date: Aug. 28, 2025

(54) MOTHER SUBSTRATE FOR DISPLAY DEVICE AND MANUFACTURING METHOD OF DISPLAY DEVICE

(71) Applicant: Japan Display Inc., Tokyo (JP)

(72) Inventor: Nobuo IMAI, Tokyo (JP)

(73) Assignee: Japan Display Inc., Tokyo (JP)

(21) Appl. No.: 19/062,076

(22) Filed: Feb. 25, 2025

(30) Foreign Application Priority Data
Feb. 26, 2024 (JP) 2024-026104

(51) Int. Cl. H10K 59/122; H10K 59/12

(52) U.S. Cl. CPC H10K 59/122; H10K 59/1201

(57) ABSTRACT

According to one embodiment, a mother substrate for a display device includes panel portions each of which includes a display area and a surrounding area, a margin area around the panel portions, a lower electrode in the display area, a rib layer which has a pixel aperture, a first partition which is in the display area and surrounds the pixel aperture, and a second partition in at least one of the surrounding area and the margin area. The first partition includes a lower portion and an upper portion which has an end portion protruding from a side surface of the lower portion. The second partition includes a first portion which includes the lower portion and which does not include the upper portion.

### CROSS-REFERENCE TO RELATED APPLICATIONS

This application is based upon and claims the benefit of priority from Japanese Patent Application No. 2024-026104, filed Feb. 26, 2024, the entire contents of which are incorporated herein by reference.

### FIELD

Embodiments described herein relate generally to a mother substrate for a display device and a manufacturing method of a display device.

### BACKGROUND

Recently, display devices to which an organic light emitting diode (OLED) is applied as a display element have been put into practical use. When this type of display device is manufactured, an inspection for confirming whether or not the elements provided on the substrate are formed as designed is implemented. A technique for implementing this inspection effectively or with high accuracy is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is the schematic cross-sectional view of a display panel along the III-III line of FIG. 2.

FIG. 4 is a schematic plan view of a mother substrate according to the first embodiment.

FIG. 5 is a schematic plan view of part of the mother substrate according to the first embodiment.

FIG. 6 is a schematic plan view showing an example of a configuration which can be applied to a test pattern according to the first embodiment.

FIG. 7 is the schematic cross-sectional view of the mother substrate along the VII-VII line of FIG. 6.

FIG. 8 is a flowchart showing an example of the manufacturing method of the display device according to the first embodiment.

FIG. 9A is a schematic cross-sectional view showing the process of forming panel portions in the mother substrate according to the first embodiment.

FIG. 9B is a schematic cross-sectional view showing a process following FIG. 9A.

FIG. 9C is a schematic cross-sectional view showing a process following FIG. 9B.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 9G is a schematic cross-sectional view showing a process following FIG. 9F.

FIG. 9H is a schematic cross-sectional view showing a process following FIG. 9G.

FIG. 9I is a schematic cross-sectional view showing a process following FIG. 9H.

FIG. 9J is a schematic cross-sectional view showing a process following FIG. 9I.

FIG. 10A is a schematic cross-sectional view showing the process of removing a rib layer in a terminal portion.

FIG. 10B is a schematic cross-sectional view showing a process following FIG. 10A.

FIG. 11A is a schematic cross-sectional view showing an example of the process of removing an upper portion from the partition of the test pattern according to the first embodiment.

FIG. 11B is a schematic cross-sectional view showing a process following FIG. 11A.

FIG. 11C is a schematic cross-sectional view showing a process following FIG. 11B.

FIG. 12 is a schematic cross-sectional view showing an example of a measurement process according to the first embodiment.

FIG. 13 is a schematic plan view showing an example of a measurement process according to the first embodiment.

FIG. 14A is a schematic cross-sectional view showing part of the manufacturing process of a display device according to a second embodiment.

FIG. 14B is a schematic cross-sectional view showing a process following FIG. 14A.

FIG. 14C is a schematic cross-sectional view showing a process following FIG. 14B.

FIG. 14D is a schematic cross-sectional view showing a process following FIG. 14C.

FIG. 15 is a schematic plan view of a test pattern according to a third embodiment.

### DETAILED DESCRIPTION

In general, according to one embodiment, a mother substrate for a display device comprises a plurality of panel portions each of which includes a display area and a surrounding area located around the display area, a margin area around the panel portions, a lower electrode in the display area, a rib layer which has a pixel aperture overlapping the lower electrode, a first partition which is in the display area and surrounds the pixel aperture, and a second partition in at least one of the surrounding area and the margin area. The first partition includes a lower portion and an upper portion which has an end portion protruding from a side surface of the lower portion. The second partition comprises a first portion which includes the lower portion and which does not include the upper portion.

According to another embodiment, a manufacturing method of a display device includes preparing a substrate which includes panel portions each including a display area and a surrounding area located around the display area, and a margin area located around the panel portions, forming a lower electrode in the display area, forming a rib layer which covers the panel portions and the margin area, forming, in the display area, a first partition which includes a lower portion and an upper portion having an end portion protruding from a side surface of the lower portion, forming a second partition which includes the lower portion and the upper portion in at least one of the margin area and the surrounding area, and performing an etching process for removing the upper portion of a first portion of the second partition.

According to the embodiments, when a display device is manufactured, an inspection can be implemented effectively or with high accuracy.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

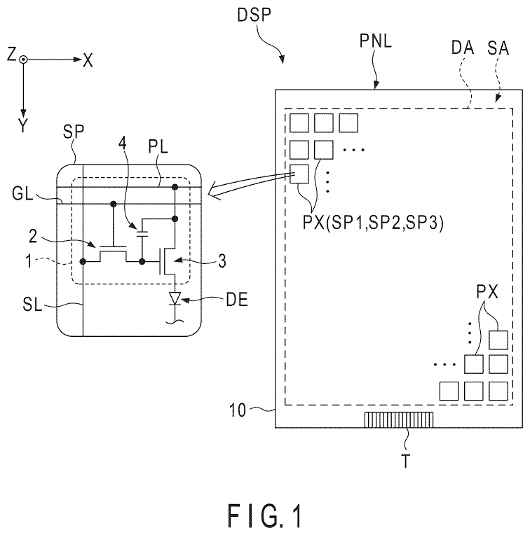

FIG. 1 is a diagram showing a configuration example of a display device DSP according to a first embodiment. The display device DSP comprises a display panel PNL including an insulating substrate 10. The display panel PNL has a display area DA which displays an image, and a surrounding area SA located around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply a scanning signal to the pixel circuit 1 of each subpixel SP, a plurality of signal lines SL which supply a video signal to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

The display device DSP further comprises a terminal portion T provided in the surrounding area SA. For example, a flexible printed circuit is connected to the terminal portion T. The signals and voltage for driving the pixel circuits 1 are input to the display device DSP via these flexible printed circuit and terminal portion T.

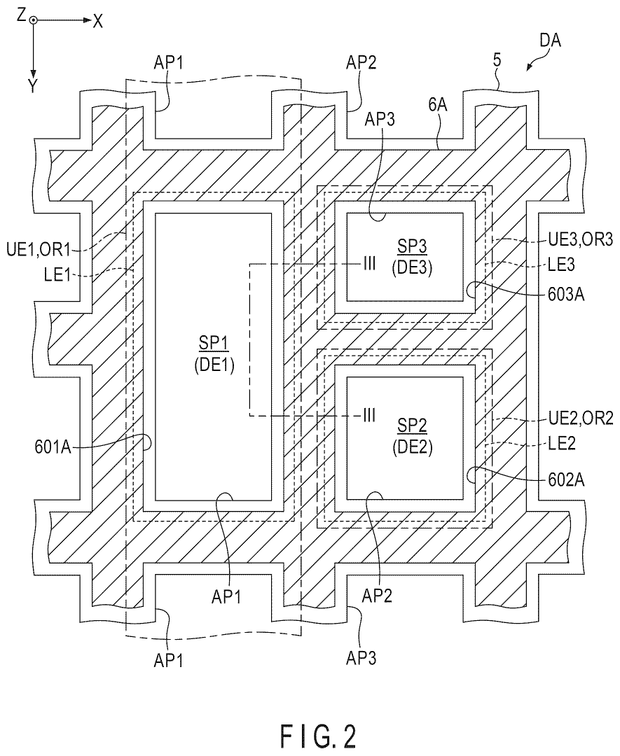

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition (first partition) 6A is provided above the rib layer 5. The partition 6A functions as lines which apply common voltage to the upper electrodes UE1, UE2 and UE3. The partition 6A overlaps the rib layer 5 as a whole and has a planar shape similar to that of the rib layer 5.

Specifically, the partition 6A has a partition aperture 601A in subpixel SP1, has a partition aperture 602A in subpixel SP2 and has a partition aperture 603A in subpixel SP3. The partition apertures 601A, 602A and 603A are larger than the pixel apertures AP1, AP2 and AP3, respectively. The partition apertures 601A, 602A and 603A overlap the display elements DE1, DE2 and DE3, respectively, as a whole. In other words, the partition 6A surrounds the display elements DE1, DE2 and DE3.

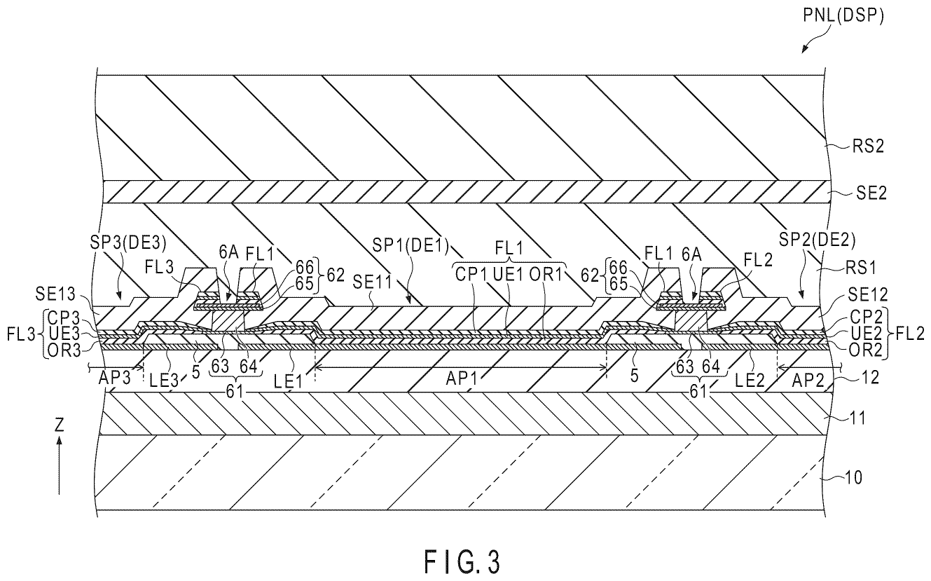

FIG. 3 is the schematic cross-sectional view of the display panel PNL along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion 61 provided on the rib layer 5, and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6A is called an overhang shape.

In the example of FIG. 3, the lower portion 61 comprises a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

In the example of FIG. 3, the upper portion 62 comprises a first top layer 65, and a second top layer 66 provided on the first top layer 65. For example, the width of the second top layer 66 is slightly less than that of the first top layer 65. It should be noted that the configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the lower portions 61 of the partition 6A.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

Sealing layers SE11, SE12 and SE13 are provided in subpixels SP1, SP2 and SP3, respectively. The sealing layer SE11 continuously covers the stacked film FL1 and the partition 6A around subpixel SP1. The sealing layer SE12 continuously covers the stacked film FL2 and the partition 6A around subpixel SP2. The sealing layer SE13 continuously covers the stacked film FL3 and the partition 6A around subpixel SP3.

In the example of FIG. 3, the sealing layer SE11 located on the partition 6A between subpixels SP1 and SP2 is spaced apart from the sealing layer SE12 located on this partition 6A. The sealing layer SE11 located on the partition 6A between subpixels SP1 and SP3 is spaced apart from the sealing layer SE13 located on this partition 6A. As another example, the end portion of the sealing layer SE11 and the end portion of the sealing layer SE12 may overlap each other on the partition 6A. Similarly, the end portion of the sealing layer SE11 and the end portion of the sealing layer SE13 may overlap each other on the partition 6A.

In the example of FIG. 3, each of the stacked films FL1, FL2 and FL3 is partly located on the partition 6A. These stacked films FL1, FL2 and FL3 are partly covered with the sealing layers SE11, SE12 and SE13, respectively. As another example, at least one of the stacked films FL1, FL2 and FL3 may not be provided on the partition 6A.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the lower portion 61 of the partition 6A is formed of, for example, a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material. Further, the lower portion 64 may consist of a single layer.

The first top layer 65 of the partition 6A is formed of, for example, a metal material. The second top layer 66 of the partition 6A is formed of, for example, a conductive oxide. For the metal material forming the first top layer 65, for example, titanium, titanium nitride, molybdenum, tungsten, a molybdenum-tungsten alloy or a molybdenum-niobium alloy can be used. For the conductive oxide forming the second top layer 66, for example, ITO or IZO can be used. It should be noted that the upper portion 62 may comprise three or more layers or may consist of a single layer. Further, the upper portion 62 may include a layer formed of an insulating material.

Common voltage is applied to the partition 6A. This common voltage is applied to each of the upper electrodes UE1, UE2 and UE3 which are in contact with the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

When the display device DSP is manufactured, a large mother substrate in which a plurality of areas (panel portions) each corresponding to the display panel PNL are formed is prepared. A configuration which may be applied to this mother substrate is explained below.

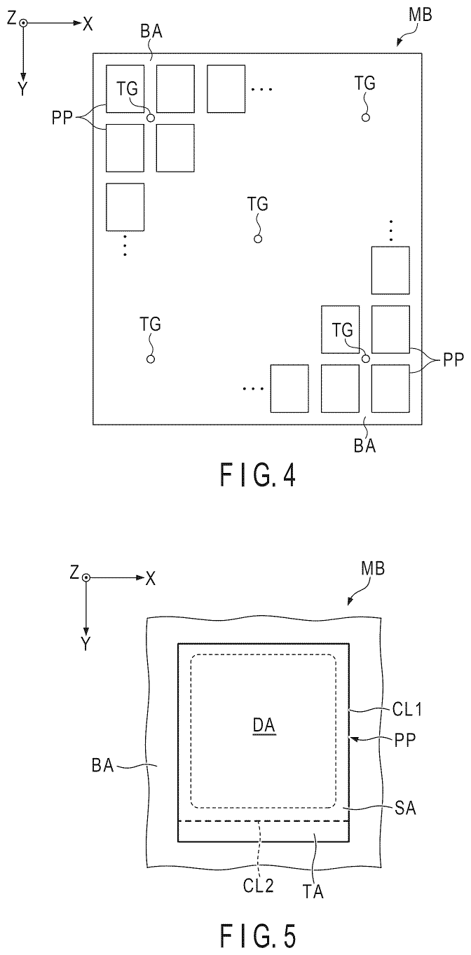

FIG. 4 is a schematic plan view of a mother substrate MB (a mother substrate for a display device) according to the embodiment. The mother substrate MB is, for example, rectangular as shown in the figure. However, the mother substrate MB may have another shape such as a circle.

The mother substrate MB comprises a plurality of panel portions PP provided in matrix, and a margin area BA located around these panel portions PP. In the example of FIG. 4, the panel portions PP are arranged via the margin area BA in the X-direction and the Y-direction. However, at least two of the panel portions PP provided in the mother substrate MB may be adjacent to each other without intervention of the margin area BA.

The mother substrate MB further comprises at least one test pattern TG. In the example of FIG. 4, a plurality of test patterns TG are provided in the margin area BA. The layout position of each test pattern TG or the number of test patterns TG is not particularly limited. However, for example, it is preferable that the test patterns TG should be dispersed at several positions such as the vicinity of the end portion and the center of the mother substrate MB.

FIG. 5 is a schematic plan view of part of the mother substrate MB. This figure focuses attention on one panel portion PP. The outer shape of the panel portion PP corresponds to a cut line CL1 for cutting the panel portion PP from the mother substrate MB.

Each panel portion PP has the display area DA and surrounding area SA described above. Further, the surrounding area SA includes an inspection area TA. In the inspection area TA, an inspection pad for inspecting the operation of the display panel PNL and the like are provided.

In each panel portion PP, a cut line CL2 is formed. By this cut line CL2, the panel portion PP is divided into a portion which includes the display area DA and a portion which includes the inspection area TA.

When the display device DSP is manufactured, first, each panel portion PP is cut out from the mother substrate MB along the cut line CL1. Further, an inspection using the inspection pad described above is implemented for the cut panel portion PP. After this inspection, the inspection area TA is separated from the panel portion PP along the cut line CL2.

The test patterns TG shown in FIG. 4 may be provided in the surrounding area SA as well as the margin area BA. For example, the test pattern TG may be provided in the inspection area TA. In this case, the test pattern TG does not remain in the panel portion PP from which the inspection area TA has been separated along the cut line CL2. In a case where the test patterns TG are provided in the margin area BA as shown in FIG. 4, similarly, the test patterns TG do not remain in the panel portions PP from which the inspection areas TA have been separated along the cut lines CL2.

As another example, the test pattern TG may be provided in the portion excluding the inspection area TA from the surrounding area SA. In this case, the test pattern TG remains in the panel portion PP from which the inspection area TA has been separated along the cut line CL2.

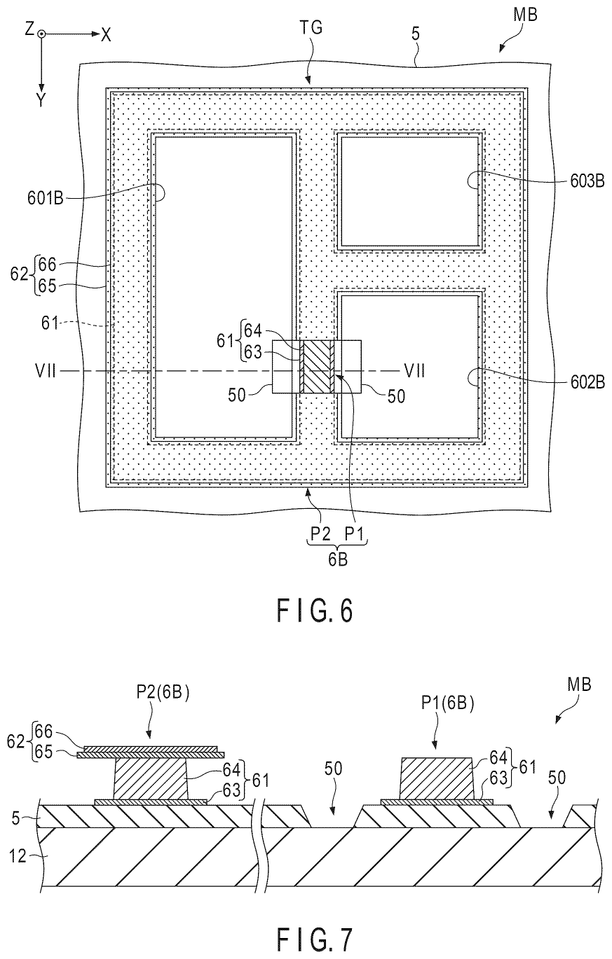

FIG. 6 is a schematic plan view showing an example of a configuration which can be applied to the test pattern TG. FIG. 7 is the schematic cross-sectional view of the mother substrate MB along the VII-VII line of FIG. 6. In FIG. 7, the elements of the lower side of the organic insulating layer 12 are omitted.

As shown in FIG. 6, the test pattern TG consists of a partition (second partition) 6B. In the example of FIG. 6, the partition 6B has partition apertures 601B, 602B and 603B.

For example, the shapes and layout of the partition apertures 601B, 602B and 603B are similar to those of the partition apertures 601A, 602A and 603A shown in FIG. 2. It should be noted that the partition 6B may have an aperture or a plurality of apertures having shapes different from those of the partition apertures 601A, 602A and 603A. The partition 6B may not have any aperture.

The partition 6B comprises a first portion P1 (the portion shown by the diagonal pattern) and a second portion P2 (the portion shown by the dotted pattern). In the example of FIG. 6, the first portion P1 is located between the partition apertures 601B and 602B. In the partition 6B, the portion excluding the first portion P1 corresponds to the second portion P2. It should be noted that the position at which the first portion P1 is provided is not limited to this example.

As shown in FIG. 6 and FIG. 7, the first portion P1 includes a lower portion 61 (a bottom layer 63 and a stem layer 64) in a manner similar to that of the partition 6A. It should be noted that the first portion P1 does not include the upper portion 62 (the first top layer 65 and the second top layer 66).

To the contrary, as shown in FIG. 7, the second portion P2 includes a lower portion 61 (a bottom layer 63 and a stem layer 64) and an upper portion 62 (a first top layer 65 and a second top layer 66).

In a manner similar to that of the partition 6A, in each of the first portion P1 and the second portion P2, the both end portions of the bottom layer 63 protrude from the side surfaces of the stem layer 64. In the second portion P2, the both end portions of the upper portion 62 protrude from the side surfaces of the stem layer 64.

The lower portion 61 of the partition 6B is formed of the same material as the lower portion 61 of the partition 6A. Specifically, the bottom layer 63 and stem layer 64 of the first and second portions P1 and P2 are formed of the same materials as the bottom layer 63 and stem layer 64 of the partition 6A, respectively. The thickness of the bottom layer 63 of each of the first and second portions P1 and P2 is equal to that of the bottom layer 63 of the partition 6A. The thickness of the stem layer 64 of each of the first and second portions P1 and P2 is equal to that of the stem layer 64 of the partition 6A.

The upper portion 62 of the second portion P2 is formed of the same material as the upper portion 62 of the partition 6A. Specifically, the first and second top layers 65 and 66 of the second portion P2 are formed of the same materials as the first and second top layers 65 and 66 of the partition 6A, respectively. The thickness of the first top layer 65 of the second portion P2 is equal to that of the first top layer 65 of the partition 6A. The thickness of the second top layer 66 of the second portion P2 is equal to that of the second top layer 66 of the partition 6A.

In FIG. 6, the outer shape of the lower portion 61 of the second portion P2 is shown by broken lines. For example, the lower portion 61 of the second portion P2 is connected to the lower portion 61 of the first portion P1.

As shown in FIG. 7, the lower portion 61 of each of the first and second portions P1 and P2 is provided on the rib layer 5. In the example of FIG. 6 and FIG. 7, the rib layer 5 has a pair of apertures 50 located around the first portion P1. The first portion P1 is located between these apertures 50 as seen in plan view. It should be noted that, in place of the apertures 50, recess portions having a shape similar to that of the apertures 50 may be formed in the rib layer 5.

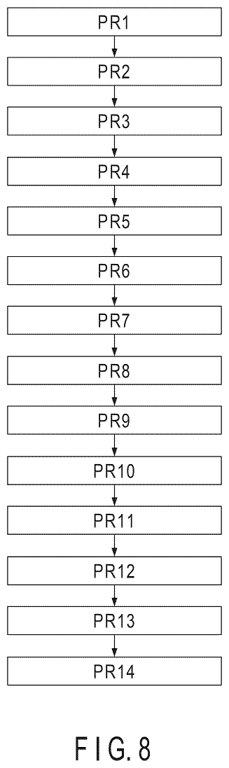

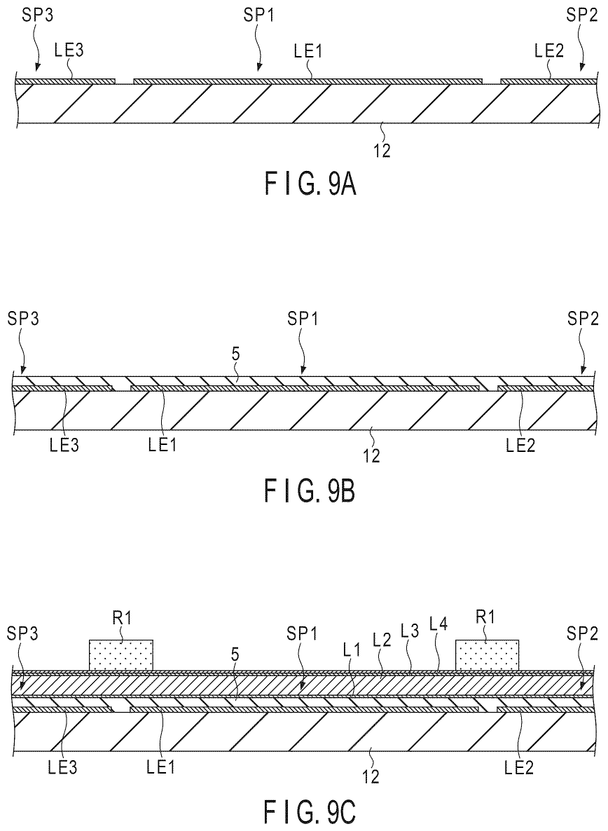

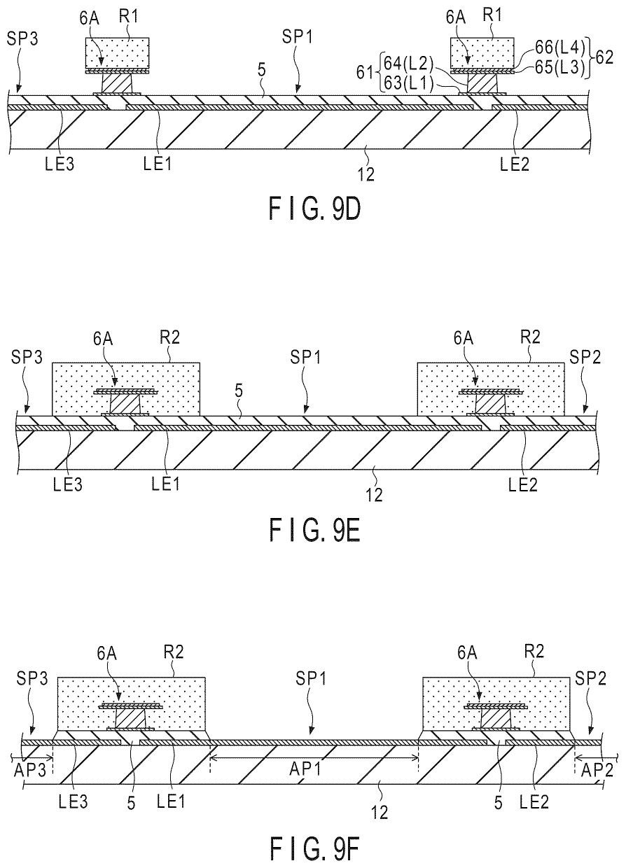

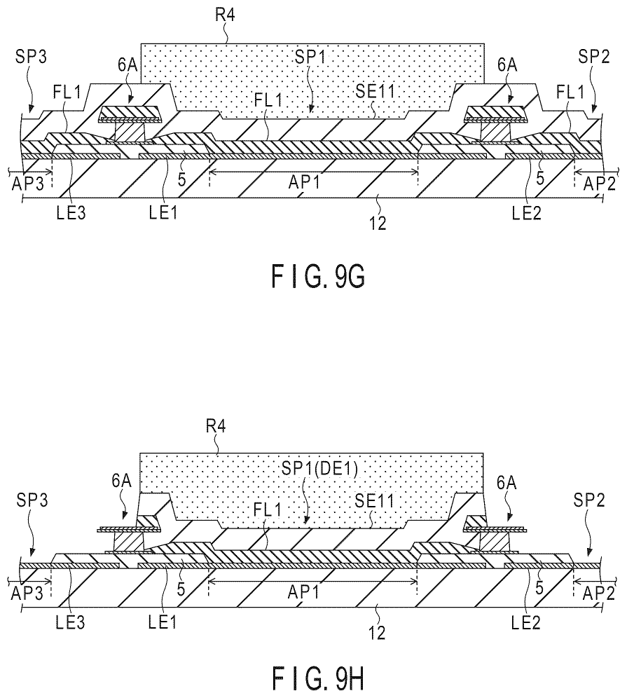

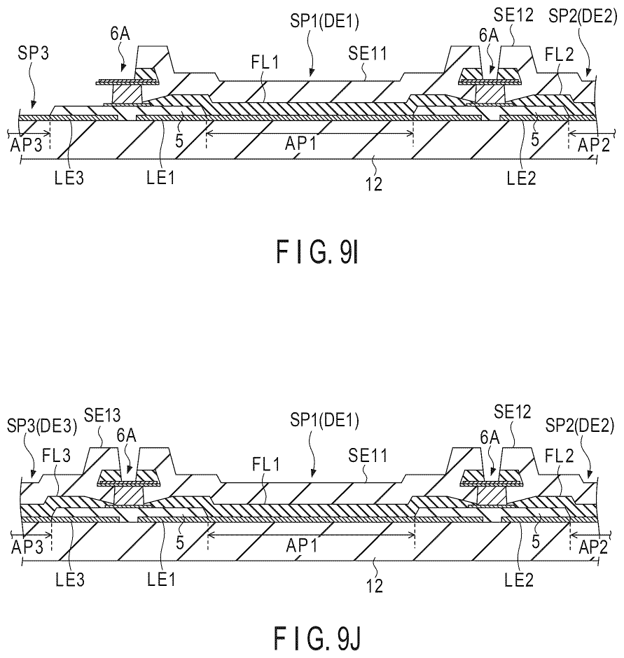

Now, this specification explains an example of the manufacturing method of the display device DSP. FIG. 8 is a flowchart showing an example of the manufacturing method of the display device DSP. FIG. 9A to FIG. 9J are schematic cross-sectional views showing the process of forming the panel portions PP in the mother substrate MB. In FIG. 9A to FIG. 9J, the display area DA is mainly looked at, and the elements located under the organic insulating layer 12 are omitted.

To form the panel portions PP, first, the circuit layer 11 and the organic insulating layer 12 are formed on the substrate 10 of the mother substrate MB (process PR1 in FIG. 8). Subsequently, as shown in FIG. 9A, the lower electrodes LE1, LE2 and LE3 are formed on the organic insulating layer 12 (process PR2 in FIG. 8).

Subsequently, as shown in FIG. 9B, the rib layer 5 which covers the lower electrodes LE1, LE2 and LE3 is formed in the entire mother substrate MB (process PR3 in FIG. 8). At this time, the pixel aperture AP1, AP2 or AP3 is not provided in the rib layer 5. The rib layer 5 may be formed by chemical vapor deposition (CVD).

After the formation of the rib layer 5, a process for forming the partition 6A is performed (processes PR4 and PR5 in FIG. 8). In process PR4, as shown in FIG. 9C, a first layer L1 which is processed so as to be the bottom layer 63, a second layer L2 which is processed so as to be the stem layer 64, a third layer L3 which is processed so as to be the first top layer 65 and a fourth layer L4 which is processed so as to be the second top layer 66 are formed in order in the entire mother substrate MB. Further, a resist R1 is provided on the fourth layer L4. The resist R1 has been patterned into the shape of the partition 6A. The first layer L1, the second layer L2, the third layer L3 and the fourth layer L4 are formed by, for example, sputtering.

In the subsequent process PR5, the first layer L1, the second layer L2, the third layer L3 and the fourth layer L4 are patterned using the resist R1 as a mask. For example, the first layer L1 is formed of titanium nitride. The second layer L2 is formed of aluminum. The third layer L3 is formed of titanium. The fourth layer L4 is formed of ITO. In this case, process PR5 may include wet etching for removing the portion of the fourth layer L4 exposed from the resist R1, dry etching for removing the portions of the first, second and third layers L1, L2 and L3 exposed from the resist R1, and wet etching for reducing the width of the second layer L2. It should be noted that the etching performed in process PR5 is appropriately selected based on the structure and material of the partition 6A.

Through process PR5, as shown in FIG. 9D, the partition 6A is formed in the display area DA. After the formation of the partition 6A, the resist R1 is removed (peeled off). In the above wet etching for reducing the width of the second layer L2, the second top layer 66 (fourth layer L4) could be slightly corroded. When this corrosion occurs, the width of the second top layer 66 becomes less than that of the first top layer 65.

Subsequently, a process for providing the pixel apertures AP1, AP2 and AP3 is performed (process PR6 in FIG. 8). In this process PR6, as shown in FIG. 9E, a resist R2 which covers the partition 6A is formed. Further, dry etching for the rib layer 5 is performed using the resist R2 as a mask. By this process, as shown in FIG. 9F, the pixel apertures AP1, AP2 and AP3 from which the lower electrodes LE1, LE2 and LE3 are exposed are formed in the rib layer 5. After the dry etching described above, the resist R2 is removed (peeled off).

After process PR6, a process for removing the rib layer 5 in the terminal portion T shown in FIG. 1 is performed (process PR7 in FIG. 8).

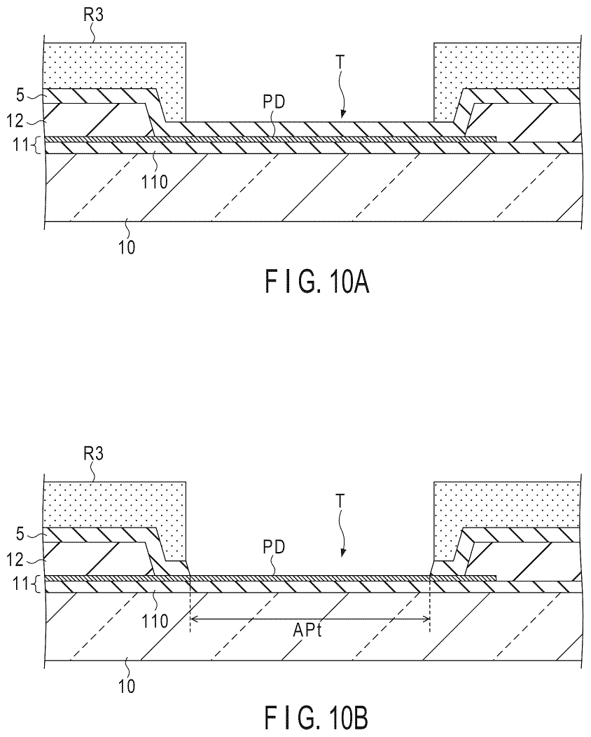

FIG. 10A and FIG. 10B are schematic cross-sectional views of the terminal portion T for explaining process PR7. As shown in these figures, the terminal portion T comprises a conductive pad PD. The pad PD is provided on an insulating layer 110 formed of, for example, an inorganic insulating material. The pad PD and the insulating layer 110 are included in the circuit layer 11 shown in, for example, FIG. 3. For example, the peripheral portion of the pad PD is covered with the organic insulating layer 12.

At the time point when process PR6 is completed, as shown in FIG. 10A, the pad PD is covered with the rib layer 5. In process PR7, a resist R3 which has a shape which is open on the upper side of the pad PD is provided on the rib layer 5. Further, dry etching for the rib layer 5 is performed using the resist R3 as a mask. By this process, as shown in FIG. 10B, a terminal aperture APt from which the pad PD is exposed is formed in the rib layer 5. After the dry etching described above, the resist R3 is removed (peeled off).

After process PR7, a process for forming the display element DE1 is performed (process PR8 in FIG. 8). To form the display element DE1, first, as shown in FIG. 9G, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 may be formed by, for example, vapor deposition. The sealing layer SE11 may be formed by, for example, CVD.

The stacked film FL1 and the sealing layer SE11 are formed in the entire mother substrate MB including the surrounding area SA and the margin area BA as well as the display area DA of each panel portion PP. The stacked film FL1 is divided into a plurality of portions by the partition 6A having an overhang shape. The sealing layer SE11 continuously covers the portions into which the stacked film FL1 is divided, and the partition 6A.

Subsequently, the stacked film FL1 and the sealing layer SE11 are patterned. In this patterning, as shown in FIG. 9G, a resist R4 is provided on the sealing layer SE11. The resist R4 covers subpixel SP1 and part of the partition 6A around the subpixel.

Subsequently, an etching process using the resist R4 a mask is performed. By this process, as shown in FIG. 9H, the portions of the stacked film FL1 and the sealing layer SE11 exposed from the resist R4 are removed. In other words, of the stacked film FL1 and the sealing layer SE11, the portions which overlap the lower electrode LE1 remain, and the other portions are removed. By this process, the display element DE1 is formed in subpixel SP1. For example, in the surrounding area SA and the margin area BA, the stacked film FL1 and the sealing layer SE11 are removed by this etching process. This etching process may include wet etching and dry etching processes which are performed in order for the sealing layer SE11, the cap layer CP1, the upper electrode UE1 and the organic layer OR1. After these etching processes, the resist R4 is removed (peeled off).

After process PR8, a process for forming the display element DE2 is performed (process PR9 in FIG. 8). The display element DE2 can be formed by a procedure similar to that of the display element DE1. Specifically, to form the display element DE2, the stacked film FL2 and the sealing layer SE12 are formed in the entire mother substrate MB. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 may be formed by, for example, vapor deposition. The sealing layer SE12 may be formed by, for example, CVD. The stacked film FL2 is divided into a plurality of portions by the partition 6A having an overhang shape. The sealing layer SE12 continuously covers the portions into which the stacked film FL2 is divided, and the partition 6A. By patterning these stacked film FL2 and sealing layer SE2, the display element DE2 is formed in subpixel SP2 as shown in FIG. 9I. For example, in the surrounding area SA and the margin area BA, the stacked film FL2 and the sealing layer SE12 are removed by the etching at the time of this patterning.

After process PR9, a process for forming the display element DE3 is performed (process PR10 in FIG. 8). The display element DE3 can be formed by a procedure similar to the procedures of the display elements DE1 and DE2. Specifically, to form the display element DE3, the stacked film FL3 and the sealing layer SE13 are formed in the entire mother substrate MB. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 may be formed by, for example, vapor deposition. The sealing layer SE13 may be formed by, for example, CVD. The stacked film FL3 is divided into a plurality of portions by the partition 6A having an overhang shape. The sealing layer SE13 continuously covers the portions into which the stacked film FL3 is divided, and the partition 6A. By patterning these stacked film FL3 and sealing layer SE13, the display element DE3 is formed in subpixel SP3 as shown in FIG. 9J. For example, in the surrounding area SA and the margin area BA, the stacked film FL3 and the sealing layer SE13 are removed by the etching at the time of this patterning.

Here, it is assumed that the display elements DE1, DE2 and DE3 are formed in this order. However, the display elements DE1, DE2 and DE3 may be formed in another order.

After the display elements DE1, DE2 and DE3 are formed, the resin layer RS1, sealing layer SE2 and resin layer RS2 shown in FIG. 3 are formed in order (process PR11 in FIG. 8). Further, each panel portion PP is cut out from the mother substrate MB along the cut line CL1 (process PR12 in FIG. 8).

Subsequently, an inspection is implemented for each panel portion PP (process PR13 in FIG. 8). This inspection includes, for example, the lighting inspection of each of the display elements DE1, DE2 and DE3 using the inspection pad provided in the inspection area TA. After the inspection, the inspection area TA is cut along the cut line CL2 (process PR14 in FIG. 8). By this process, the display panel PNL is completed.

The partition 6B is formed by processes PR4 and PR5 in a manner similar to that of the partition 6A. However, immediately after process PR5, the partition 6B has the upper portion 62 as a whole. In other words, the upper portion 62 is provided in the first portion P1 as well shown in FIG. 6 and FIG. 7.

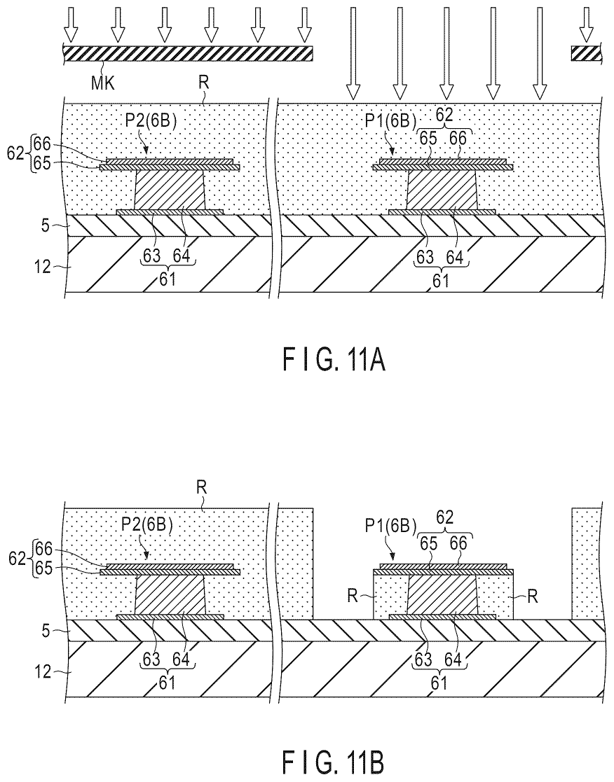

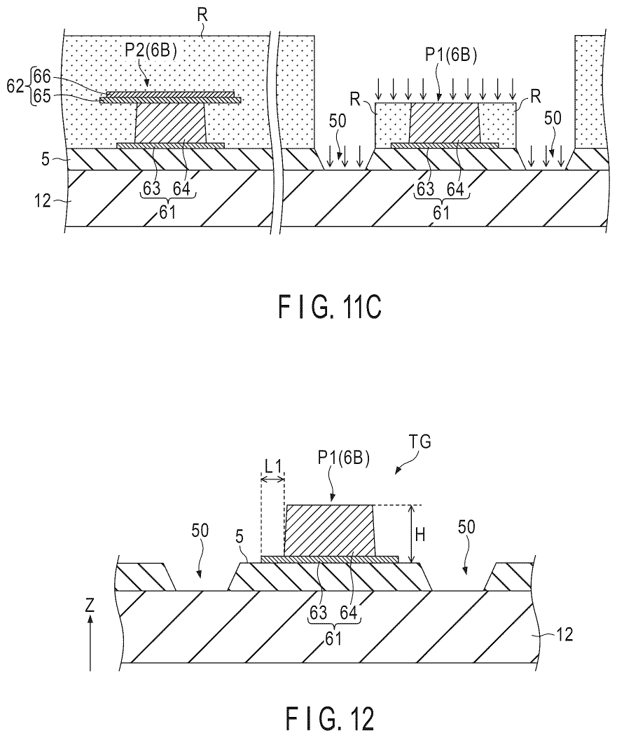

FIG. 11A to FIG. 11C are schematic cross-sectional views showing an example of the process of removing the upper portion 62 from the first portion P1. These cross-sectional views show the same portion as FIG. 7. The elements located under the organic insulating layer 12 are omitted.

To remove the upper portion 62 from the first portion P1, as shown in FIG. 11A, a resist R which covers the partition 6B is formed. Further, as shown by several arrows, the resist R is exposed to light using a mask MK. The mask MK is open on the upper side of the first portion P1. The resist R is, for example, a positive resist. Therefore, as shown in FIG. 11B, the exposed portion of the resist R is removed by a development process. In FIG. 11B, the second portion P2 is covered with the resist R as a whole. The upper portion 62 of the first portion P1 is exposed from the resist R.

For example, when the first top layer 65 is formed of a metal material, the first top layer 65 has light-shielding properties. In this case, the resist R located under the first top layer 65 is not exposed to light. Therefore, in FIG. 11B, the resist R remains under the upper portion 62 of the first portion P1.

Subsequently, an etching process is performed in a state where the resist R is provided. By this process, as shown in FIG. 11C, the upper portion 62 of the first portion P1 is removed, and the upper surface of the stem layer 64 is exposed. Since the upper portion 62 of the second portion P2 is covered with the resist R, this upper portion 62 is not removed by the etching process.

The etching process may be one type of etching (for example, dry etching) by which the first top layer 65 and the second top layer 66 are removed at the same time. As another example, the etching process may include etching for removing the second top layer 66 and etching for removing the first top layer 65. For example, when the first top layer 61 is formed of titanium, and the second top layer 66 is formed of ITO, the etching process may include wet etching for removing the second top layer 66 and dry etching for removing the first top layer 65.

When the etching process includes dry etching, the rib layer 5 exposed from the resist R could be also removed. By this process, the apertures 50 of the rib layer 5 are formed around the first portion P1. After the etching process, the resist R is removed (peeled off).

When the etching process is performed, the resist R covers the partition 6A of the display area DA as a whole. Therefore, the partition 6A is not corroded in the etching process.

The process shown in FIG. 11A to FIG. 11C may be performed at an appropriate time point after process PR5 shown in FIG. 8. As the process shown in FIG. 11A to FIG. 11C, process PR6 for forming the pixel apertures AP1, AP2 and AP3 in the rib layer 5 may be used. In this case, the resist R corresponds to the resist R2 shown in FIG. 9E. Further, the etching process for removing the upper portion 62 of the first portion P1 includes dry etching for forming the pixel apertures AP1, AP2 and AP3 in the rib layer 5.

Alternatively, as the process shown in FIG. 11A to FIG. 11C, process PR7 for forming the terminal aperture APt in the rib layer 5 may be used. In this case, the resist R corresponds to the resist R3 shown in FIG. 10A and FIG. 10B. Further, the etching process for removing the upper portion 62 of the first portion P1 includes dry etching for forming the terminal aperture APt in the rib layer 5.

After the upper portion 62 of the first portion P1 is removed, the measurement process of the test pattern TG for the partition 6B is performed. The timing of performing the measurement process is not particularly limited. For example, the measurement process is performed before the formation of the display elements DE1, DE2 and DE3 (processes PR8, PR9 and PR10).

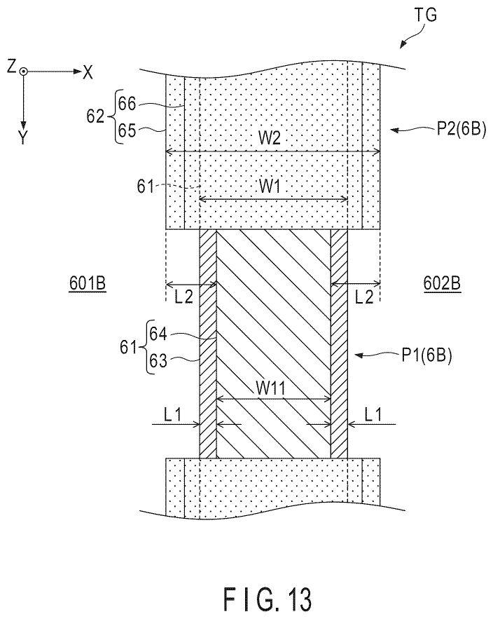

FIG. 12 is a schematic cross-sectional view showing an example of a measurement process. FIG. 13 is a schematic plan view showing an example of a measurement process. In a measurement process, as shown in FIG. 12, height H of the lower portion 61 of the first portion P1 is measured. Height H corresponds to the distance from the upper surface of the rib layer 5 to the upper surface of the stem layer 64 in the Z-direction. When height H is measured, for example, an atomic force microscope (AFM) or a white-light interference microscope may be used.

Further, in the measurement process, as shown in FIG. 12 and FIG. 13, length L1 of the bottom layer 63 which protrudes from the side surface of the stem layer 64 is measured. Length L1 corresponds to the distance between the side surface of the stem layer 64 and the end portion of the bottom layer 63 in the X-direction. Length L1 can be measured by, for example, analyzing an image obtained by capturing the first portion P1 in a planar manner.

Further, in the measurement process, as shown in FIG. 13, length L2 of the upper portion 62 which protrudes from the side surface of the stem layer 64 is measured based on the first portion P1 and the second portion P2. In the example of FIG. 13, length L2 corresponds to the distance between the side surface of the stem layer 64 and the end portion of the first top layer 65 in the X-direction. Length L2 can be measured by, for example, analyzing an image obtained by capturing the first portion P1 and the second portion P2 in a planar manner.

Both the first portion P1 and the second portion P2 shown in FIG. 13 are located between the partition apertures 601B and 602B and extend in the Y-direction. The lower portion 61 of each of the first and second portions P1 and P2 has width W1. Width W1 corresponds to the width of the bottom layer 63 in the X-direction. Width W1 is the sum of width W11 of the stem layer 64 in the X-direction and the double of length L1. In the lower portion 61 of the first portion P1 and the lower portion 61 of the second portion P2 adjacent to the first portion P1, these width W11 and length L1 are equal.

In this case, length L2 can be obtained by, for example, multiplying the difference between width W2 of the upper portion 62 of the second portion P2 and width W11 of the stem layer 64 of the first portion P1 by ½. In the example of FIG. 13, width W2 corresponds to the width of the first top layer 65 in the X-direction. Length L2 may be obtained by measuring the length of the first top layer 65 of the second portion P2 which protrudes from the side surface of the stem layer 64 of the first portion P1 at the boundary between the first portion P1 and the second portion P2.

Height H, length L1 and length L2 obtained in the measurement process are used for an inspection regarding whether or not the partition 6A is normally formed. In other words, as the partitions 6A and 6B are formed by the same process (processes PR4 and PR5 in FIG. 8), height H, length L1 and length L2 measured regarding the partition 6B can be regarded as height H, length L1 and length L2 of the partition 6A, respectively. When at least one of height H, length L1 and length L2 is outside an allowable range determined in advance, the manufacturing process subsequent to the measurement process may be suspended.

The measurement process may be performed regarding each of the test patterns TG which are dispersed in the mother substrate MB as shown in FIG. 4. In this case, variations caused in measurement depending on each position of the mother substrate MB can be prevented. As another example, the measurement process may be performed for some of the test patterns TG.

As explained above, in the embodiment, a measurement process is performed using the first portion P1 which does not include the upper portion 62. If the entire partition 6B includes the upper portion 62, height H, length L1 and length L2 need to be measured through a destructive inspection for observing the section of the partition 6B. The destructive inspection is difficult to perform in the middle of the manufacturing process of the display device DSP, and further, requires time and effort.

To the contrary, when the first portion P1 which does not include the upper portion 62 is provided in the test patterns TG like the embodiment, height H, length L1 and length L2 can be measured by an observation from the upper side of the mother substrate MB without the need for the destructive inspection. This measurement can be easily performed in the middle of the manufacturing process of the display device DSP. When a failure is confirmed in an inspection using the measurement results, the manufacturing can be suspended without performing the subsequent process.

In addition, as described above, when process PR6 for forming the pixel apertures AP1, AP2 and AP3 in the rib layer 5 is used as the process of removing the upper portion 62 from the partition 6B, the number of processing steps can be reduced. This effect can be also obtained when process PR7 for forming the terminal aperture APt in the rib layer 5 is used.

When the partition 6B of each test pattern TG has a shape similar to that of the partition 6A as shown in FIG. 6, the improvement of the consistency between the measurement results of height H, length L1 and length L2 for the partition 6B and the actual height H, length L1 and length L2 of the partition 6A can be expected.

Thus, according to the embodiment, when the display device DSP is manufactured, an inspection can be implemented effectively and with high accuracy. Various desirable effects can be obtained from the embodiment in addition to the effects explained here.

### Second Embodiment

A second embodiment is explained. The same elements as the first embodiment are denoted by the same reference numbers. Thus, overlapping explanations are omitted.

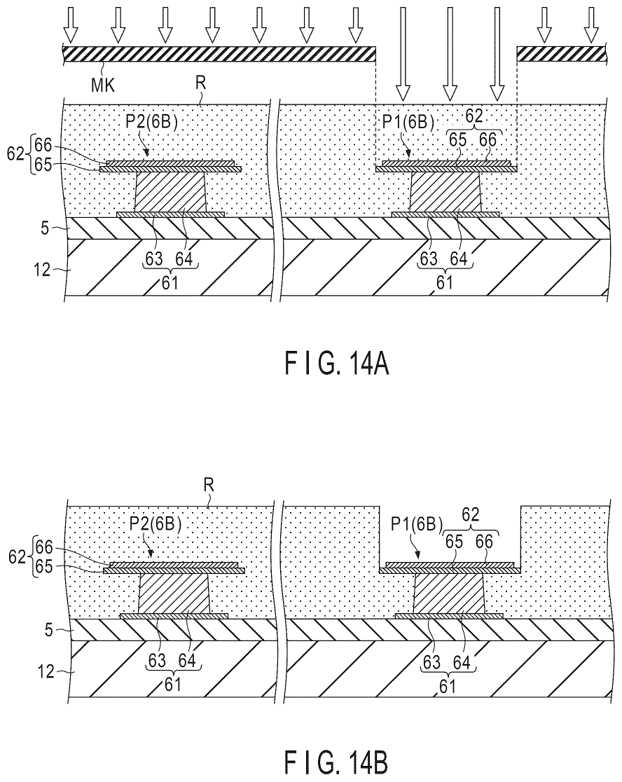

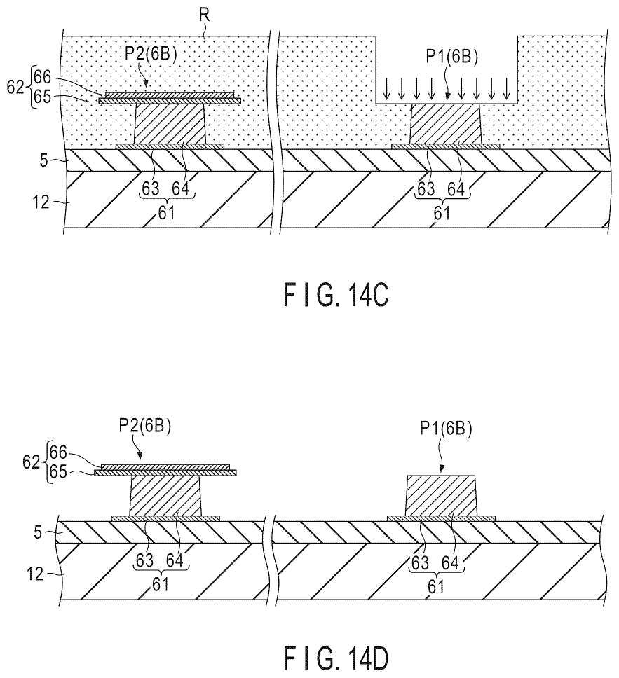

FIG. 14A to FIG. 14D are schematic cross-sectional views showing part of the manufacturing process of a display device DSP according to the second embodiment. Specifically, these drawings show an example of the process of removing an upper portion 62 from a first portion P1 in a manner similar to that of FIG. 11A to FIG. 11C.

In the example of FIG. 14A, in a manner similar to that of FIG. 11A, a positive resist R which covers a partition 6B is formed. Further, as shown by several arrows, the resist R is exposed to light using a mask MK. The mask MK is open on the upper side of the first portion P1. The aperture width of the mask MK is equal to the width of the upper portion 62 (in FIG. 14A, the width of a first top layer 65).

By a development process subsequent to this exposure, as shown in FIG. 14B, the exposed portion of the resist R is removed. In FIG. 14B, a second portion P2 is covered with the resist R as a whole. The upper portion 62 of the first portion P1 is exposed from the resist R. Since the aperture width of the mask MK is equal to the width of the upper portion 62, the resist R located around the first portion P1 is not removed. Therefore, a rib layer 5 located around the first portion P1 is not exposed from the resist R.

Subsequently, an etching process is performed in a state where the resist R is provided. By this process, as shown in FIG. 14C, the upper portion 62 of the first portion P1 is removed. The shape of the first portion P1 formed in this manner is similar to that of the example of FIG. 11C. However, in FIG. 14C, the apertures 50 of the rib layer 5 are not formed.

After the etching process described above, the resist R is removed (peeled off) as shown in FIG. 14D. A measurement process similar to that of the first embodiment is performed using the first and second portions P1 and P2 formed in the above manner. Even in this case, effects similar to those of the first embodiment can be obtained.

### Third Embodiment

A third embodiment is explained. The same elements as the first embodiment are denoted by the same reference numbers. Thus, overlapping explanations are omitted.

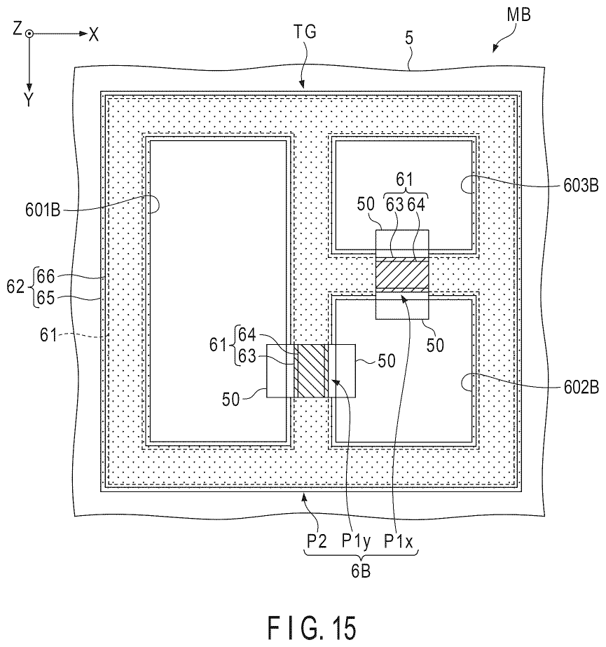

FIG. 15 is a schematic plan view of a test pattern TG according to the third embodiment. In the example of this figure, two first portions P1 (P1x and Ply) are provided in one test pattern TG.

The first portion Ply is similar to the first portion P1 shown in FIG. 6 and is located between partition apertures 601B and 602B. The first portion P1x is located between the partition apertures 602B and 603B.

From another viewpoint, the first portion Ply is provided at a position extending in a Y-direction in a partition 6B. The first portion P1x is provided at a position extending in an X-direction in the partition 6B.

In the example of FIG. 15, a plurality of apertures 50 adjacent to the first portions P1x and Ply are provided in a rib layer 5. It should be noted that the rib layer 5 may not have the apertures 50 in a manner similar to that of the second embodiment.

For example, the measurement process described above is performed for both the first portion P1x and the first portion Ply. If values such as height H, length L1 and length L2 could vary depending on the direction in which the partitions 6A and 6B extend, the measurement can be more accurately performed by applying the configuration of this embodiment.

It should be noted that the number of first portions P1 provided in one test pattern TG may be three or greater. All of FIG. 6 to FIG. 15 show examples in which the area of the first portion P1 is less than that of the second portion P2. However, the area of the first portion P1 may be greater than that of the second portion.

All of the display devices, mother substrates and manufacturing methods that can be implemented by a person of ordinary skill in the art through arbitrary design changes to the display device, mother substrate and manufacturing method disclosed in the embodiments described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A mother substrate for a display device, the mother substrate comprising:
a plurality of panel portions each of which includes a display area and a surrounding area located around the display area;
a margin area around the panel portions;
a lower electrode in the display area;
a rib layer which has a pixel aperture overlapping the lower electrode;
a first partition which is in the display area and surrounds the pixel aperture; and
a second partition in at least one of the surrounding area and the margin area, wherein
the first partition includes a lower portion and an upper portion which has an end portion protruding from a side surface of the lower portion, and
the second partition comprises a first portion which includes the lower portion and which does not include the upper portion.

2. The mother substrate of claim 1, wherein
in each of the first partition and the second partition, the lower portion is provided on the rib layer.

3. The mother substrate of claim 1, wherein
in each of the first partition and the second partition, the lower portion includes a bottom layer and a stem layer provided on the bottom layer.

4. The mother substrate of claim 3, wherein
an end portion of the bottom layer protrudes from a side surface of the stem layer.

5. The mother substrate of claim 3, wherein
the bottom layer of the first partition and the bottom layer of the second partition are formed of a same material.

6. The mother substrate of claim 3, wherein
the stem layer of the first partition and the stem layer of the second partition are formed of a same material.

7. The mother substrate of claim 1, wherein
the rib layer has an aperture around the first portion.

8. The mother substrate of claim 1, wherein
the second partition further comprises a second portion which includes the lower portion and the upper portion.

9. The mother substrate of claim 8, wherein
the upper portion of the first partition and the upper portion of the second portion are formed of a same material.

10. The mother substrate of claim 8, wherein
a width of the lower portion of the first portion and a width of the lower portion of at least part of the second portion are equal to each other.

11. The mother substrate of claim 8, wherein
the lower portion of the first portion and the lower portion of the second portion are connected to each other.

12. A manufacturing method of a display device, the method including:
preparing a substrate which includes panel portions each including a display area and a surrounding area around the display area, and a margin area around the panel portions;
forming a lower electrode in the display area;
forming a rib layer which covers the panel portions and the margin area;
forming, in the display area, a first partition which includes a lower portion and an upper portion having an end portion protruding from a side surface of the lower portion;
forming a second partition which includes the lower portion and the upper portion in at least one of the margin area and the surrounding area; and
performing an etching process for removing the upper portion of a first portion of the second partition.

13. The manufacturing method of claim 12, further including measuring a height of the lower portion of the first portion from which the upper portion has been removed.

14. The manufacturing method of claim 12, wherein
in each of the first partition and the second partition, the lower portion includes a bottom layer and a stem layer located on the bottom layer, and
an end portion of the bottom layer protrudes from a side surface of the stem layer.

15. The manufacturing method of claim 14, further including measuring a length of the bottom layer which protrudes from a side surface of the stem layer in the lower portion of the first portion from which the upper portion has been removed.

16. The manufacturing method of claim 12, wherein
before the etching process, a resist which covers the first partition and from which the first portion of the second partition is exposed is provided, and
the upper portion of the first portion is removed by performing the etching process in a state where the resist is provided.

17. The manufacturing method of claim 16, wherein
the resist covers a second portion of the second partition, and
after the etching process, the second portion has the lower portion and the upper portion.

18. The manufacturing method of claim 17, further including measuring a length of the upper portion which protrudes from the side surface of the lower portion based on the first portion and the second portion.

19. The manufacturing method of claim 14, further including forming a pixel aperture from which the lower electrode is exposed in the rib layer by the etching process.

20. The manufacturing method of claim 14, further including forming a terminal aperture from which a conductive pad located under the rib layer is exposed in the rib layer by the etching process.
